(19) United States
(12) Patent Application Publication
(10) Pub. No.: US 2015/0236749 A1
(43) Pub. Date: Aug. 20, 2015

(54) RADIO FREQUENCY SWITCHING CIRCUIT

(71) Applicant: SAMSUNG ELECTRO-MECHANICS CO., LTD., Suwon-Si (KR)

(72) Inventors: Jae Hyouck CHOI, Suwon-Si (KR); Suk Chan KANG, Suwon-Si (KR); Kyu Jin CHOI, Suwon-Si (KR); Jeong Hoon KIM, Suwon-Si (KR)

(73) Assignee: SAMSUNG ELECTRO-MECHANICS CO., LTD., Suwon-Si (KR)

(21) Appl. No.: 14/270,989

(22) Filed: May 6, 2014

(30) Foreign Application Priority Data
Feb. 17, 2014 (KR) 10-2014-0017854

(51) Int. Cl. H04B 1/48; H03K 17/56

(52) U.S. Cl. CPC H04B 1/48; H03K 17/56

(57) ABSTRACT

A radio frequency switching circuit may include: a first switching circuit unit connected between a first signal port for transmitting and receiving signals and a common connection node connected to an antenna port and operated by a first gate signal; a second switching circuit unit connected between a second signal port for transmitting and receiving the signals and the common connection node and operated by a second gate signal; a signal selecting unit selecting a signal having a higher voltage between the first and second gate signals and providing the selected signal as a reference voltage; and a voltage generating unit generating a common node voltage using the reference voltage and providing the generated common node voltage to the common connection node, the common node voltage being lower than the reference voltage and being higher than a voltage level of zero.

### CROSS-REFERENCE TO RELATED APPLICATION

This application claims the benefit of Korean Patent Application No. 10-2014-0017854 filed on Feb. 17, 2014, with the Korean Intellectual Property Office, the disclosure of which is incorporated herein by reference.

### BACKGROUND

The present disclosure relates to a radio frequency switching circuit.

A semiconductor integrated circuit embedded in a communications system may include a radio frequency switching circuit controlling a transfer path of a radio frequency signal between an antenna and a transmitting unit/receiving unit. The radio frequency switching circuit may be used in communications systems such as a Bluetooth™ communications system, a cellular Personal Communications Service (PCS) communications system, a Code Division Multiple Access (CDMA) communications system, a Wideband Code Division Multiple Access (WCDMA) communications system, a Time Division Multiple Access (TDMA) communications system, a Global System/Standard for Mobile Communications (GSM) communications system, and the like, as well as a Wireless Local Area Network (WLAN).

Generally, a radio frequency switching circuit may be used between the transmitting unit and the receiving unit in various communications systems using Time-Division Multiplexing (TDM). Since the transmitting unit and the receiving unit are alternately turned on and off using the radio frequency switching circuit, an overall amount of power consumed by a system may be decreased, and interference between the transmitting unit and the receiving unit may also be decreased.

In the radio frequency switching circuit as described above, low insertion loss, high isolation, high switching speeds, and high power handling capabilities may be required, and low harmonic distortion, even in the case in which a large signal is input, that is, a high degree of linearity, may be required.

With regard thereto, the better the insertion loss characteristics, the lower the sensitivity deterioration of the receiving unit and transmission power loss of the transmitting unit that occur by a switch. The power handling capability may ensure maximum output power of the transmitting unit. In addition, the high isolation characteristics significantly decrease an influence of the transmitting unit on the receiving unit in a turned-off state in the case that the transmitting unit is operated, and significantly decrease an influence of the receiving unit on the transmitting unit in a turned-off state in the case that the receiving unit is operated.

Particularly, in mobile communications systems, insertion loss characteristics and power handling capabilities are additionally required among the above-mentioned characteristics.

In an existing wireless communications device, the radio frequency switching circuit includes a plurality of radio frequency ports connected to a plurality of transmitting/receiving units, respectively, and a common port connected to an antenna.

The radio frequency switching circuit controls transfer paths of radio frequency signals between the plurality of radio frequency ports and the antenna port, such that one of the plurality of transmitting/receiving units connected to the radio frequency switching circuit may be selected and electrically connected to the antenna.

An existing radio frequency switching circuit may include a switching circuit unit connected between the respective radio frequency ports and the antenna port and a shunt circuit unit connected between the respective radio frequency ports and a ground, in order to switch transfer paths of radio frequency signals between the respective radio frequency ports and the antenna port.

Here, the switching circuit unit may include a transmit switching circuit unit Tx SW and a receive switching circuit unit Rx SW, wherein each of the transmit switching circuit unit Tx SW and the receive switching circuit unit Rx SW may include a plurality of semiconductor switches.

The semiconductor switch, a switching device formed on a silicon on insulator (SOI) substrate, may be formed of a metal oxide semiconductor field effect transistor (MOSFET).

In the existing radio frequency switching circuit, the switching circuit unit has a structure in which a plurality of transistors are stacked in order to prepare for the case in which a signal larger than a breakdown voltage of one transistor is applied.

In the structure in which the plurality of transistors are stacked, a voltage higher than a rated voltage is divided and applied to each of the plurality of transistors. Therefore, a voltage applied to one transistor is decreased, such that the transistor may be protected from a high voltage.

In the existing radio frequency switching circuit as described above, a gate signal lower or higher than a threshold voltage Vth of the transistor is provided to a gate of each of the transistors included in the transmit switching circuit unit and the receive switching circuit unit, such that the transistor may be controlled in a turned-on state or a turned-off state. The gate signal may be provided from a base band chip set.

In the existing radio frequency switching circuit, a negative voltage generating unit implemented by a complicated circuit may be separately required in order to provide the gate signal for controlling the switching circuit unit for selecting a signal path to be in a turned-off state as a negative voltage, for the purpose of securing isolation required between the transmitting unit and the receiving unit.

In the case in which the negative voltage generating unit is separately provided, complexity in a design process and manufacturing costs increase.

The following Related Art Document (Patent Document 1), which relates to a radio frequency switching circuit and a method of controlling the same, does not disclose a technical feature that a common node voltage is provided to a common connection node using a voltage basically provided in a system without a separate negative voltage generating unit.

### RELATED ART DOCUMENT

(Patent Document 1) Korean Patent Laid-Open Publication No. 10-2012-0070485

### SUMMARY

An aspect of the present disclosure may provide a radio frequency switching circuit capable of providing a common node voltage to a common connection node using a voltage basically provided in a system without a separate negative voltage generating unit.

According to an aspect of the present disclosure, a radio frequency switching circuit may include: a first switching circuit unit connected between a first signal port for transmitting and receiving signals and a common connection node connected to an antenna port and operated by a first gate signal; a second switching circuit unit connected between a second signal port for transmitting and receiving the signals and the common connection node and operated by a second gate signal; and a voltage generating unit generating a common node voltage using a preset reference voltage and providing the generated common node voltage to the common connection node, the common node voltage being lower than the reference voltage and being higher than a voltage level of zero.

The common node voltage may be lower than a high level of the first gate signal by at least a level of a turn-on voltage of a transistor included in the first switching circuit unit and be higher than a low level of the second gate signal.

The voltage generating unit may include at least first and second resistors connected to each other in series between a terminal receiving the reference voltage and a ground, and the common node voltage may be provided from a connection node between the first and second resistors.

According to another aspect of the present disclosure, a radio frequency switching circuit may include: a first switching circuit unit connected between a first signal port for transmitting and receiving signals and a common connection node connected to an antenna port and operated by a first gate signal; a second switching circuit unit connected between a second signal port for transmitting and receiving the signals and the common connection node and operated by a second gate signal; a signal selecting unit selecting a signal having a higher voltage between the first and second gate signals and providing the selected signal as a reference voltage; and a voltage generating unit generating a common node voltage using the reference voltage and providing the generated common node voltage to the common connection node, the common node voltage being lower than the reference voltage and being higher than a voltage level of zero.

The signal selecting unit may include: a first switching device connected between a first terminal receiving the first gate signal and a common terminal providing the reference voltage and turned on in the case that the first gate signal has a voltage level higher than that of the second gate signal; and a second switching device connected between a second terminal receiving the second gate signal and the common terminal and turned on in the case that the second gate signal has a voltage level higher than that of the first gate signal.

The signal selecting unit may include: a first transistor diode-connected between a first terminal receiving the first gate signal and a common terminal providing the reference voltage and turned on in the case that the first gate signal has a voltage level higher than that of the second gate signal; and a second transistor diode-connected between a second terminal receiving the second gate signal and the common terminal and turned on in the case that the second gate signal has a voltage level higher than that of the first gate signal.

The signal selecting unit may include: a first diode connected between a first terminal receiving the first gate signal and a common terminal providing the reference voltage and turned on in the case that the first gate signal has a voltage level higher than that of the second gate signal; and a second diode connected between a second terminal receiving the second gate signal and the common terminal and turned on in the case that the second gate signal has a voltage level higher than that of the first gate signal.

The common node voltage may be lower than a high level of the first gate signal by at least a level of a turn-on voltage of a transistor included in the first switching circuit unit and be higher than a low level of the second gate signal.

The voltage generating unit may include at least first and second resistors connected to each other in series between a terminal receiving the reference voltage and a ground, and the common node voltage may be provided from a connection node between the first and second resistors.

According to another aspect of the present disclosure, a radio frequency switching circuit may include: a first switching circuit unit including a plurality of transistors connected between a first signal port for transmitting and receiving signals and a common connection node connected to an antenna port and operated by a first gate signal; a second switching circuit unit including a plurality of transistors connected between a second signal port for transmitting and receiving the signals and the common connection node and operated by a second gate signal; a signal selecting unit selecting one of the first and second gate signals and providing the selected signal as a reference voltage; and a voltage generating unit generating a common node voltage using the reference voltage and providing the generated common node voltage to the common connection node, the common node voltage being lower than the reference voltage and being higher than a voltage level of zero, wherein the signal selecting unit includes: a first switching device turned on in the case that the first gate signal has a voltage level higher than that of the second gate signal; and a second switching device turned on in the case that the second gate signal has a voltage level higher than that of the first gate signal.

The first switching device may be connected between a first terminal receiving the first gate signal and a common terminal providing the reference voltage, and the second switching device may be connected between a second terminal receiving the second gate signal and the common terminal.

The first switching device may include a first transistor diode-connected between a first terminal receiving the first gate signal and a common terminal providing the reference voltage and turned on in the case that the first gate signal has a voltage level higher than that of the second gate signal, and the second switching device may include a second transistor diode-connected between a second terminal receiving the second gate signal and the common terminal and turned on in the case that the second gate signal has a voltage level higher than that of the first gate signal.

The first switching device may include a first diode connected between a first terminal receiving the first gate signal and a common terminal providing the reference voltage and turned on in the case that the first gate signal has a voltage level higher than that of the second gate signal, and the second switching device may include a second diode connected between a second terminal receiving the second gate signal and the common terminal and turned on in the case that the second gate signal has a voltage level higher than that of the first gate signal.

The common node voltage may be lower than a high level of the first gate signal by at least a level of a turn-on voltage of the transistor included in the first switching circuit unit and be higher than a low level of the second gate signal.

The voltage generating unit may include at least first and second resistors connected to each other in series between a terminal receiving the reference voltage and a ground, and the common node voltage may be provided from a connection node between the first and second resistors.

According to another aspect of the present disclosure, a radio frequency switching circuit may include: a first switching circuit unit including a plurality of transistors connected between a first signal port for transmitting and receiving signals and a common connection node connected to an antenna port and operated by a first gate signal; a second switching circuit unit including a plurality of transistors connected between a second signal port for transmitting and receiving the signals and the common connection node and operated by a second gate signal; a signal selecting unit selecting one of the first and second gate signals and providing the selected signal as a reference voltage; and a voltage generating unit generating a common node voltage using the reference voltage and providing the generated common node voltage to the common connection node, the common node voltage being lower than a high level of the first gate signal by at least a level of a turn-on voltage of the transistor included in the first switching circuit unit and being higher than a low level of the second gate signal wherein the signal selecting unit includes: a first switching device turned on in the case that the first gate signal has a voltage level higher than that of the second gate signal, thereby selecting the first gate signal and providing the first gate signal as the reference voltage; and a second switching device turned on in the case that the second gate signal has a voltage level higher than that of the first gate signal, thereby selecting the second gate signal and providing the second gate signal as the reference voltage.

The first switching device may be connected between a first terminal receiving the first gate signal and a common terminal providing the reference voltage, and the second switching device may be connected between a second terminal receiving the second gate signal and the common terminal.

The first switching device may include a first transistor diode-connected between a first terminal receiving the first gate signal and a common terminal providing the reference voltage and turned on in the case that the first gate signal has a voltage level higher than that of the second gate signal, thereby selecting the first gate signal and providing the first gate signal as the reference voltage, and the second switching device may include a second transistor diode-connected between a second terminal receiving the second gate signal and the common terminal and turned on in the case that the second gate signal has a voltage level higher than that of the first gate signal, thereby selecting the second gate signal and providing the second gate signal as the reference voltage.

The first switching device may include a first diode connected between a first terminal receiving the first gate signal and a common terminal providing the reference voltage and turned on in the case that the first gate signal has a voltage level higher than that of the second gate signal, thereby selecting the first gate signal and providing the first gate signal as the reference voltage, and the second switching device may include a second diode connected between a second terminal receiving the second gate signal and the common terminal and turned on in the case that the second gate signal has a voltage level higher than that of the first gate signal, thereby selecting the second gate signal and providing the second gate signal as the reference voltage.

The voltage generating unit may include at least first and second resistors connected to each other in series between a terminal receiving the reference voltage and a ground, and the common node voltage may be provided from a connection node between the first and second resistors.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a diagram illustrating a configuration of a radio frequency switching circuit according to an exemplary embodiment of the present disclosure;

FIG. 2 is a diagram illustrating another configuration of a radio frequency switching circuit according to an exemplary embodiment of the present disclosure;

FIG. 3 is a diagram illustrating a configuration of a signal selecting unit according to an exemplary embodiment of the present disclosure;

FIG. 4 is a diagram illustrating another configuration of a signal selecting unit according to an exemplary embodiment of the present disclosure;

FIG. 5 is a diagram illustrating another configuration of a signal selecting unit according to an exemplary embodiment of the present disclosure;

FIG. 6 is a diagram illustrating a configuration of a voltage generating unit according to an exemplary embodiment of the present disclosure; and

FIG. 7 is a graph for describing harmonic characteristics of the radio frequency switching circuit according to an exemplary embodiment of the present disclosure.

### DETAILED DESCRIPTION

Hereinafter, embodiments of the present disclosure will be described in detail with reference to the accompanying drawings. The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art. Throughout the drawings, the same or like reference numerals will be used to designate the same or like elements.

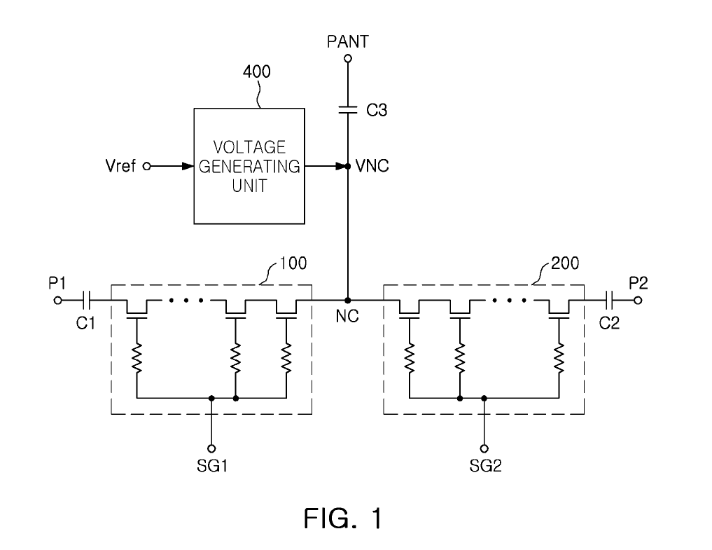

FIG. 1 is a diagram illustrating a configuration of a radio frequency switching circuit according to an exemplary embodiment of the present disclosure.

Referring to FIG. 1, a radio frequency switching circuit according to an exemplary embodiment of the present disclosure may include a first switching circuit unit 100, a second switching circuit unit 200, and a voltage generating unit 400.

The first switching circuit unit 100 may be connected between a first signal port P1 for transmitting and receiving signals and a common connection node NC connected to an antenna port PANT and be operated by a first gate signal SG1. The first switching circuit unit 100 may include a plurality of transistors connected to each other in series and operated by the first gate signal SG1.

Each of the plurality of transistors of the first switching circuit unit 100 may be turned on in the case that the first gate signal SG1 is in a high level (for example, 3V), and may be turned off in the case that the first gate signal SG1 is in a low level (for example, 0V).

The second switching circuit unit 200 may be connected between a second signal port P2 for transmitting and receiving the signals and the common connection node NC and be operated by a second gate signal SG2. The second switching circuit unit 200 may include a plurality of transistors connected to each other in series and operated by the second gate signal SG2.

Each of the plurality of transistors of the second switching circuit unit 200 may be turned on in the case that the second gate signal SG2 is in a high level (for example, 3V), and may be turned off in the case that the second gate signal SG2 is in a low level (for example, 0V).

Here, each of the first and second gate signals SG1 and SG2 may be high level or low level and may have phases opposite to each other.

Meanwhile, each of the plurality of transistors included in each of the first and second switching circuit units 100 and 200, a semiconductor device formed on a silicon on insulator (SOI) substrate, may be a metal oxide semiconductor field effect transistor (MOSFET).

The voltage generating unit 400 may generate a common node voltage VNC using a preset reference voltage Vref and provide the generated common node voltage VNC to the common connection node NC, wherein the common node voltage is lower than the reference voltage Vref and is higher than a voltage level of zero.

The reference voltage Vref may be basically provided in a system to which the radio frequency switching circuit according to an exemplary embodiment of the present disclosure is applied. Alternatively, the reference voltage Vref may be generated using a gate signal for controlling the radio frequency switching circuit according to an exemplary embodiment of the present disclosure, as described below. Here, the reference voltage Vref, a positive voltage lower than a voltage of the gate signal that is in a high level, may be different from a negative voltage.

The common node voltage VNC may be lower than the high level of the first gate signal SG1 by at least a turn-on voltage of the transistor included in the first switching circuit unit 100 and be higher than the low level of the second gate signal SG2.

For example, in the case that the high level and the low level of each of the first and second gate signals SG1 and SG2 are 3V and 0V, respectively, and the turn-on voltage of the transistor is 0.7V, the common node voltage VNC may be lower than 2.3V and higher than 0V, for example, 1.5V.

For example, in the case in which the first gate signal SG1 is in the high level (for example, 3V) and the second gate signal SG2 is in the low level (0V), in the case that the common node voltage VNC becomes 1.5V, all of the plurality of transistors of the first switching circuit unit 100 may be turned on, and all of the plurality of transistors of the second switching circuit unit 200 may be turned off.

In this case, since the common node voltage VNC of 1.5V is provided to the common connection node NC during a period in which the second gate signal of 0V is provided to a gate of each of the plurality of transistors of the second switching circuit unit 200, an effect that it seems that −1.5V is provided as a gate signal may be generated. Therefore, each of the plurality of transistors of the second switching circuit unit 200 may be maintained in the turned-off state even in a large signal, such that linearity may be improved.

Unlike this, in the case in which the second gate signal SG2 is in the high level (for example, 1V) and the first gate signal SG1 is in the low level (0V), in the case that the common node voltage VNC becomes 1.5V, all of the plurality of transistors of the second switching circuit unit 200 may be turned on, and all of the plurality of transistors of the first switching circuit unit 100 may be turned off.

In this case, since the common node voltage VNC of 1.5V is provided to the common connection node NC during a period in which the first gate signal SG1 of 0V is provided to a gate of each of the plurality of transistors of the first switching circuit unit 100, an effect that it seems that −1.5V is provided as a gate signal may be generated. Therefore, each of the plurality of transistors of the first switching circuit unit 100 may be maintained in the turned-off state even in a large signal, such that linearity may be improved.

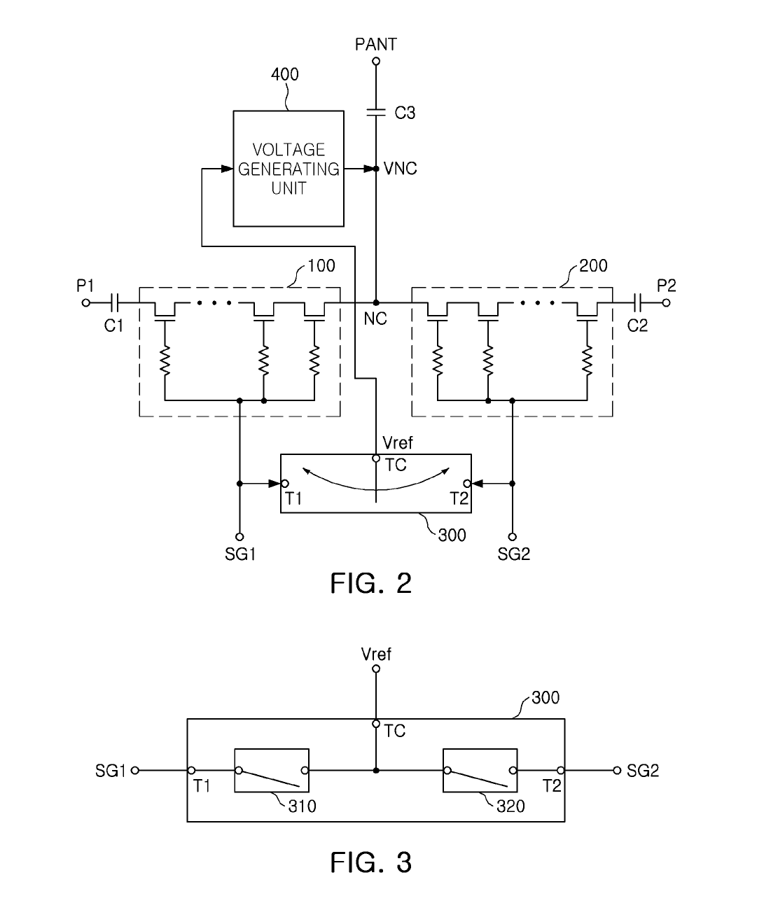

FIG. 2 is a diagram illustrating another configuration of a radio frequency switching circuit according to an exemplary embodiment of the present disclosure.

Referring to FIG. 2, a radio frequency switching circuit according to an exemplary embodiment of the present disclosure may include a first switching circuit unit 100, a second switching circuit unit 200, a signal selecting unit 300, and a voltage generating unit 400.

A description for operations of the first switching circuit unit 100, the second switching circuit unit 200, and the voltage generating unit 400 of FIG. 2 that are the same as the operations described above with reference to FIG. 1 will be omitted in order to avoid an overlapped description.

Referring to FIG. 2, the signal selecting unit 300 may select a signal having a higher voltage between the first and second gate signals SG1 and SG2 and provide the selected signal as the reference voltage Vref.

In FIGS. 1 and 2, each of C1, C2, and C3 may a blocking capacitor passing a radio frequency (RF) signal therethrough and blocking direct current (DC) power.

FIG. 3 is a diagram illustrating a configuration of a signal selecting unit according to an exemplary embodiment of the present disclosure.

Referring to FIG. 3, the signal selecting unit 300 may include a first switching device 310 and a second switching device 320.

The first switching device 310 may be connected between a first terminal T1 receiving the first gate signal SG1 and a common terminal TC providing the reference voltage Vref. The first switching device 310 may be turned on in the case that the first gate signal SG1 has a voltage level higher than that of the second gate signal SG2, thereby providing the first gate signal SG1 as the reference voltage Vref.

The second switching device 320 may be connected between a second terminal T2 receiving the second gate signal SG2 and the common terminal TC. The second switching device 320 may be turned on in the case that the second gate signal SG2 has a voltage level higher than that of the first gate signal SG1, thereby providing the second gate signal SG2 as the reference voltage Vref.

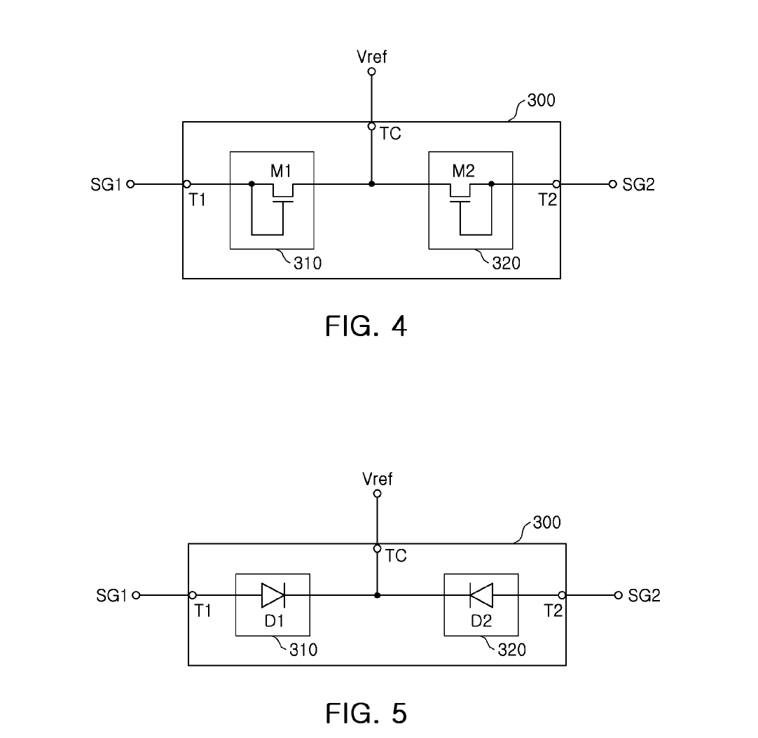

FIG. 4 is a diagram illustrating another configuration of a signal selecting unit according to an exemplary embodiment of the present disclosure.

Referring to FIGS. 3 and 4, a first switching device 310 of the signal selecting unit 300 may include a first transistor M1, and a second switching device 320 thereof may include a second transistor M2.

The first transistor M1 may be diode-connected between a first terminal T1 receiving the first gate signal SG1 and a common terminal TC providing the reference voltage Vref.

For example, a source and a gate of the first transistor M1 may be connected to the first terminal T1, and a drain thereof may be connected to the common terminal TC. Here, the first transistor M1 may be turned on in the case that a voltage level of the first gate signal SG1 is higher than that of the second gate signal SG2 by a turn-on voltage or more of the first transistor M1.

When the first transistor M1 is turned on, the first gate signal SG1 may be provided as the reference voltage Vref to the voltage generating unit 400 through the first transistor M1 and the common terminal TC.

The second transistor M2 may be diode-connected between a second terminal T2 receiving the second gate signal SG2 and the common terminal TC providing the reference voltage Vref.

For example, a source and a gate of the second transistor M2 may be connected to the second terminal T2, and a drain thereof may be connected to the common terminal TC. Here, the second transistor M2 may be turned on in the case that a voltage level of the second gate signal SG2 is higher than that of the first gate signal SG1 by a turn-on voltage or more of the second transistor M2.

When the second transistor M2 is turned on, the second gate signal SG2 may be provided as the reference voltage Vref to the voltage generating unit 400 through the second transistor M2 and the common terminal TC.

FIG. 5 is a diagram illustrating another configuration of a signal selecting unit according to an exemplary embodiment of the present disclosure.

Referring to FIGS. 3 and 5, a first switching device 310 of the signal selecting unit 300 may include a first diode D1, and a second switching device 320 thereof may include a second diode D2.

The first diode D1 may be connected between a first terminal T1 receiving the first gate signal SG1 and a common terminal TC providing the reference voltage Vref.

For example, an anode of the first diode D1 may be connected to the first terminal T1, and a cathode thereof may be connected to the common terminal TC. Here, the first diode D1 may be turned on in the case that a voltage level of the first gate signal SG1 is higher than that of the second gate signal SG2 by a turn-on voltage or more of the first diode D1.

When the first diode D1 is turned on, the first gate signal SG1 may be provided as the reference voltage Vref to the voltage generating unit 400 through the first diode D1 and the common terminal TC.

The second diode D2 may be connected between a second terminal T2 receiving the second gate signal SG2 and the common terminal TC providing the reference voltage Vref.

For example, an anode of the second diode D2 may be connected to the second terminal T2, and a cathode thereof may be connected to the common terminal TC. Here, the second diode D2 may be turned on in the case that a voltage level of the second gate signal SG2 is higher than that of the first gate signal SG1 by a turn-on voltage or more of the second diode D2.

When the second diode D2 is turned on, the second gate signal SG2 may be provided as the reference voltage Vref to the voltage generating unit 400 through the second diode D2 and the common terminal TC.

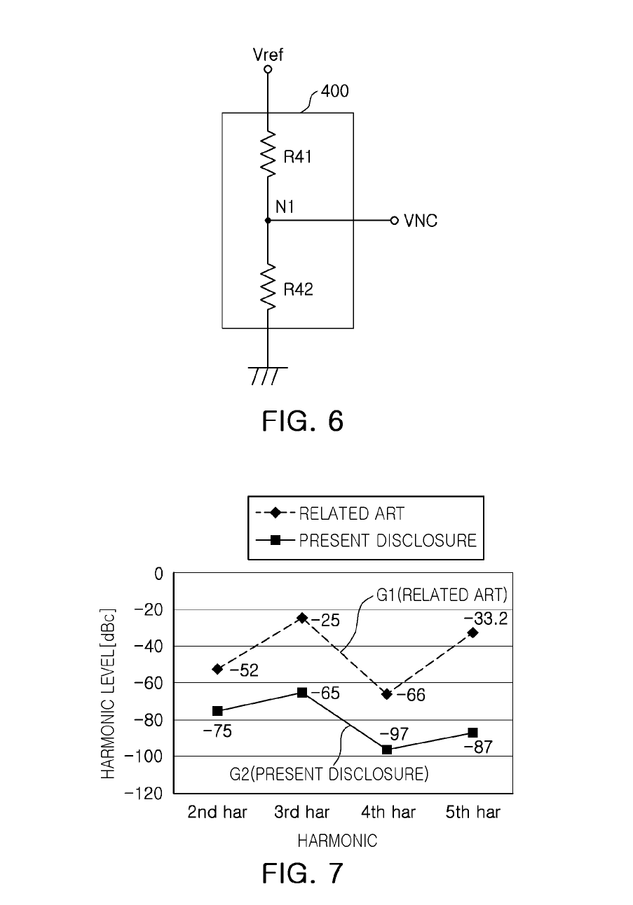

FIG. 6 is a diagram illustrating a configuration of a voltage generating unit according to an exemplary embodiment of the present disclosure.

Referring to FIGS. 1, 2, and 6, the voltage generating unit 400 may include at least first and second resistors R41 and R42 connected to each other in series between a terminal receiving the reference voltage Vref and a ground.

The common node voltage VNC may be provided from a connection node N1 between the first and second resistors R41 and R42 to the common connection node NC.

A circuit diagram shown in FIG. 6 is an example of the voltage generating unit 400, and the voltage generating unit 400 according to an exemplary embodiment of the present disclosure is not limited thereto, but may include any circuit capable of generating the common node voltage VNC using the reference voltage Vref, such as a voltage regulator, a direct current (DC) to DC converter, or the like, in addition to a dividing circuit using a resistor, wherein the common node voltage VNC is higher than a voltage level of zero and is lower than the reference voltage Vref.

FIG. 7 is a graph for describing harmonic characteristics of the radio frequency switching circuit according to an exemplary embodiment of the present disclosure.

In FIG. 7, G1 is a graph illustrating harmonic characteristics of a radio frequency switching circuit according to the related art using a gate signal simply having a high level and a low level, a voltage level of zero, without using a common node voltage, and G2 is a graph illustrating harmonic characteristics of a radio frequency switching circuit according to an exemplary embodiment of the present disclosure.

It may be appreciated that the harmonic characteristics of the radio frequency switching circuit according to an exemplary embodiment of the present disclosure were improved as compared with the related art by 20 dBc or more in the case that comparing G1 and G2 of FIG. 7 with each other.

According to an exemplary embodiment of the present disclosure as described above, the common node voltage may be provided to the common connection node using the voltage (reference voltage or gate signal) basically provided in the system without a separate negative voltage generating unit of which implementation is complicated, such that a gate signal of a negative voltage may be provided. Therefore, the harmonic characteristics may be improved, such that distortion may be decreased even in a large signal as compared with the related art, whereby the linearity may be relatively improved.

As set forth above, according to exemplary embodiments of the present disclosure, the common node voltage may be provided to the common connection node using the voltage basically provided in the system without a separate negative voltage generating unit, such that the gate signal of the negative voltage may be provided.

While exemplary embodiments have been shown and described above, it will be apparent to those skilled in the art that modifications and variations could be made without departing from the spirit and scope of the present disclosure as defined by the appended claims.

What is claimed is:

1. A radio frequency switching circuit comprising:
a first switching circuit unit connected between a first signal port for transmitting and receiving signals and a common connection node connected to an antenna port and operated by a first gate signal;
a second switching circuit unit connected between a second signal port for transmitting and receiving the signals and the common connection node and operated by a second gate signal; and
a voltage generating unit generating a common node voltage using a preset reference voltage and providing the generated common node voltage to the common connection node, the common node voltage being lower than the reference voltage and being higher than a voltage level of zero.

2. The radio frequency switching circuit of claim 1, wherein the common node voltage is lower than a high level of the first gate signal by at least a level of a turn-on voltage of a transistor included in the first switching circuit unit and is higher than a low level of the second gate signal.

3. The radio frequency switching circuit of claim 1, wherein the voltage generating unit includes at least first and second resistors connected to each other in series between a terminal receiving the reference voltage and a ground, and
the common node voltage is provided from a connection node between the first and second resistors.

4. A radio frequency switching circuit comprising:
a first switching circuit unit connected between a first signal port for transmitting and receiving signals and a common connection node connected to an antenna port and operated by a first gate signal;
a second switching circuit unit connected between a second signal port for transmitting and receiving the signals and the common connection node and operated by a second gate signal;
a signal selecting unit selecting a signal having a higher voltage between the first and second gate signals and providing the selected signal as a reference voltage; and
a voltage generating unit generating a common node voltage using the reference voltage and providing the generated common node voltage to the common connection node, the common node voltage being lower than the reference voltage and being higher than a voltage level of zero.

5. The radio frequency switching circuit of claim 4, wherein the signal selecting unit includes:
a first switching device connected between a first terminal receiving the first gate signal and a common terminal providing the reference voltage and turned on in the case that the first gate signal has a voltage level higher than that of the second gate signal; and
a second switching device connected between a second terminal receiving the second gate signal and the common terminal and turned on in the case that the second gate signal has a voltage level higher than that of the first gate signal.

6. The radio frequency switching circuit of claim 4, wherein the signal selecting unit includes:
a first transistor diode-connected between a first terminal receiving the first gate signal and a common terminal providing the reference voltage and turned on in the case that the first gate signal has a voltage level higher than that of the second gate signal; and
a second transistor diode-connected between a second terminal receiving the second gate signal and the common terminal and turned on in the case that the second gate signal has a voltage level higher than that of the first gate signal.

7. The radio frequency switching circuit of claim 4, wherein the signal selecting unit includes:
a first diode connected between a first terminal receiving the first gate signal and a common terminal providing the reference voltage and turned on in the case that the first gate signal has a voltage level higher than that of the second gate signal; and
a second diode connected between a second terminal receiving the second gate signal and the common terminal and turned on in the case that the second gate signal has a voltage level higher than that of the first gate signal.

8. The radio frequency switching circuit of claim 4, wherein the common node voltage is lower than a high level of the first gate signal by at least a level of a turn-on voltage of a transistor included in the first switching circuit unit and is higher than a low level of the second gate signal.

9. The radio frequency switching circuit of claim 4, wherein the voltage generating unit includes at least first and second resistors connected to each other in series between a terminal receiving the reference voltage and a ground, and
the common node voltage is provided from a connection node between the first and second resistors.

10. A radio frequency switching circuit comprising:
a first switching circuit unit including a plurality of transistors connected between a first signal port for transmitting and receiving signals and a common connection node connected to an antenna port and operated by a first gate signal;
a second switching circuit unit including a plurality of transistors connected between a second signal port for transmitting and receiving the signals and the common connection node and operated by a second gate signal;
a signal selecting unit selecting one of the first and second gate signals and providing the selected signal as a reference voltage; and
a voltage generating unit generating a common node voltage using the reference voltage and providing the generated common node voltage to the common connection node, the common node voltage being lower than the reference voltage and being higher than a voltage level of zero,
wherein the signal selecting unit includes:
a first switching device turned on in the case that the first gate signal has a voltage level higher than that of the second gate signal; and
a second switching device turned on in the case that the second gate signal has a voltage level higher than that of the first gate signal.

11. The radio frequency switching circuit of claim 10, wherein the first switching device is connected between a first terminal receiving the first gate signal and a common terminal providing the reference voltage, and
the second switching device is connected between a second terminal receiving the second gate signal and the common terminal.

12. The radio frequency switching circuit of claim 10, wherein the first switching device includes a first transistor diode-connected between a first terminal receiving the first gate signal and a common terminal providing the reference voltage and turned on in the case that the first gate signal has a voltage level higher than that of the second gate signal, and
the second switching device includes a second transistor diode-connected between a second terminal receiving the second gate signal and the common terminal and turned on in the case that the second gate signal has a voltage level higher than that of the first gate signal.

13. The radio frequency switching circuit of claim 10, wherein the first switching device includes a first diode connected between a first terminal receiving the first gate signal and a common terminal providing the reference voltage and turned on in the case that the first gate signal has a voltage level higher than that of the second gate signal, and
the second switching device includes a second diode connected between a second terminal receiving the second gate signal and the common terminal and turned on in the case that the second gate signal has a voltage level higher than that of the first gate signal.

14. The radio frequency switching circuit of claim 10, wherein the common node voltage is lower than a high level of the first gate signal by at least a level of a turn-on voltage of the transistor included in the first switching circuit unit and is higher than a low level of the second gate signal.

15. The radio frequency switching circuit of claim 10, wherein the voltage generating unit includes at least first and second resistors connected to each other in series between a terminal receiving the reference voltage and a ground, and
the common node voltage is provided from a connection node between the first and second resistors.

16. A radio frequency switching circuit comprising:
a first switching circuit unit including a plurality of transistors connected between a first signal port for transmitting and receiving signals and a common connection node connected to an antenna port and operated by a first gate signal;
a second switching circuit unit including a plurality of transistors connected between a second signal port for transmitting and receiving the signals and the common connection node and operated by a second gate signal;
a signal selecting unit selecting one of the first and second gate signals and providing the selected signal as a reference voltage; and
a voltage generating unit generating a common node voltage using the reference voltage and providing the generated common node voltage to the common connection node, the common node voltage being lower than a high level of the first gate signal by at least a level of a turn-on voltage of the transistor included in the first switching circuit unit and being higher than a low level of the second gate signal
wherein the signal selecting unit includes:
a first switching device turned on in the case that the first gate signal has a voltage level higher than that of the second gate signal, thereby selecting the first gate signal and providing the first gate signal as the reference voltage; and
a second switching device turned on in the case that the second gate signal has a voltage level higher than that of the first gate signal, thereby selecting the second gate signal and providing the second gate signal as the reference voltage.

17. The radio frequency switching circuit of claim 16, wherein the first switching device is connected between a first terminal receiving the first gate signal and a common terminal providing the reference voltage, and
the second switching device is connected between a second terminal receiving the second gate signal and the common terminal.

18. The radio frequency switching circuit of claim 16, wherein the first switching device includes a first transistor diode-connected between a first terminal receiving the first gate signal and a common terminal providing the reference voltage and turned on in the case that the first gate signal has a voltage level higher than that of the second gate signal, thereby selecting the first gate signal and providing the first gate signal as the reference voltage, and
the second switching device includes a second transistor diode-connected between a second terminal receiving the second gate signal and the common terminal and turned on in the case that the second gate signal has a voltage level higher than that of the first gate signal, thereby selecting the second gate signal and providing the second gate signal as the reference voltage.

19. The radio frequency switching circuit of claim 16, wherein the first switching device includes a first diode connected between a first terminal receiving the first gate signal and a common terminal providing the reference voltage and turned on in the case that the first gate signal has a voltage level higher than that of the second gate signal, thereby selecting the first gate signal and providing the first gate signal as the reference voltage, and
the second switching device includes a second diode connected between a second terminal receiving the second gate signal and the common terminal and turned on in the case that the second gate signal has a voltage level higher than that of the first gate signal, thereby selecting the second gate signal and providing the second gate signal as the reference voltage.

20. The radio frequency switching circuit of claim 16, wherein the voltage generating unit includes at least first and second resistors connected to each other in series between a terminal receiving the reference voltage and a ground, and
the common node voltage is provided from a connection node between the first and second resistors.
